(19) United States
(12) Patent Application Publication
(10) Pub. No.: US 2009/0098741 A1
(43) Pub. Date: Apr. 16, 2009

(54) METHOD FOR FORMING ULTRA-THIN BORON-CONTAINING NITRIDE FILMS AND RELATED APPARATUS

(75) Inventors: Rei Tanaka, Tokyo (JP); Takashige Watanabe, Tokyo (JP); Hideaki Fukuda, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM Japan K.K., Tokyo (JP)

(21) Appl. No.: 11/872,619

(22) Filed: Oct. 15, 2007

(51) Int. Cl. H01L 21/31; B05C 11/00

(52) U.S. Cl. 438/791; 118/696; 257/E21.24

(57) ABSTRACT

Boron-containing nitride films, including silicon boron nitride and boron nitride films, are deposited during, e.g., integrated circuit fabrication. The films are deposited in a process chamber having a reaction space that is defined as an open volume of the chamber directly above the substrate. The boron-containing nitride films are formed by flowing silicon and boron precursors into the process chamber while maintaining the volume, as measured under standard conditions, of silicon and boron precursors, e.g., SiH₄ and B₂H₆, flowed into the process chamber per minute at about 6.2% or less of the volume of the reaction space. In some embodiments, N₂ is flowed into the process chamber at a flow rate of about 100 times the total flow rate of the silicon and boron precursors. The deposited films have good film thickness controllability and high in-plane film thickness uniformity for use as, e.g., etch stop layers.

### BACKGROUND OF THE INVENTION

1. Field of the Invention

This invention relates to semiconductor processing and, more particularly, to semiconductor processing equipment and methods for forming boron-containing nitride films.

2. Description of the Related Art

The fabrication of semiconductor devices, such as contained in integrated circuits, typically involves defining patterns in various materials. The patterns are defined by etching the materials, thereby forming various parts of the semiconductor devices. The etching process can be stopped by strategically placing a material resistant to the etch at positions where one desires to stop the etch. For example, a layer of material resistant to the etch can be placed underneath a layer being etched, so that the etch effectively stops after etching through the layer being etched. The etch resistant materials are typically referred as etch stop materials and a layer of these materials is typically referred to as an etch stop layer (ESL).

For example, a copper (Cu) damascene process can be used to form electrically conductive features, such as interconnects, in a semiconductor device or integrated circuit. In some processes, insulating materials are etched to form trenches or holes, which are later filled with copper. A silicon nitride (SiN) film is used as an ESL in some cases to stop etching when wire trenches and vertical wiring connection holes (via holes) are processed in an inter-layer insulating film made of SiO, SiOC, etc., using reactive ion etching (RIE).

While etch resistant, it will be appreciated that the ESL can still be etched to some extent by the etch process. To guard against over-etching and possibly etching through the ESL, it can be beneficial to have a relatively thick ESL.

However, increasing the film thickness is not desirable since this can cause the effective dielectric constant (the combination of the dielectric constant of the ESL and the insulating film overlying the ESL) to rise. Due to design requirements, the insulating film and the ESL typically have a target effective dielectric constant. For example, when the total thickness of an inter-layer insulation film, with a specific dielectric constant of 2.4, and an ESL is assumed to be 260 nm, and the allowable effective specific dielectric constant as 2.53, calculations based on SiN having a dielectric constant of 6.5 indicate that the maximum SiN film thickness is about 8 nm or so.

Although generalizations are difficult because whether a SiN film of this thickness adequately functions as an ESL is also affected by the RIE etch conditions and the quality (etching speed) of the overlying inter-layer insulation film, it is necessary for the rate at which the SiN is etched to be low relative to the etch rate of the inter-layer insulation film, to prevent etching through the ESL. On the other hand, if the dielectric constant of the SiN were reduced to about 4.5, the possible film thickness would double to about 15.7 nm while maintaining the effective specific dielectric constant at 2.53. If the RIE etching speed is the same, doubling the film thickness doubles the margin of error for guarding against over-etching, which is advantageous in device production.

As are result, there is a need for methods and systems for depositing high quality etch stop layers with a low dielectric constant.

### SUMMARY OF SOME EMBODIMENTS

In accordance with some embodiments of the invention, a method is provided for forming a boron-containing nitride film. The method comprises providing a substrate in a process chamber having a reaction space. The reaction space is an open volume directly above the substrate and extends between the substrate and an upper electrode of the process chamber. The substrate is exposed to a boron precursor, a silicon precursor and N₂ by flowing the boron precursor, the silicon precursor and N₂ into the process chamber. A total volume, as measured under standard conditions, of the boron precursor and the silicon precursor flowed into the process chamber per minute is about 6.2% or less of the volume of the reaction space.

In accordance with other embodiments of the invention, a method is provided for semiconductor processing. The method comprises providing a substrate in a process chamber, chemical vapor depositing a boron-containing nitride film on the substrate, and terminating deposition of the boron-containing nitride film while a thickness of the deposited film is about 20 nm or less. An in-plane uniformity of the deposited boron-containing nitride film is about 3% or less.

In accordance with other embodiments of the invention, a system is provided for semiconductor processing. The system comprises a reactor comprising a process chamber for accommodating a substrate between upper and lower electrodes. The process chamber comprises a reaction space consisting of an open volume directly overlying the substrate and extending between the substrate and the upper electrode upon retention of the substrate in the process chamber. A boron precursor source is in gas communication with the process chamber. A nitrogen precursor source is in gas communication with the process chamber. A controller is programmed to simultaneously flow the boron precursor and the nitrogen precursor into the process chamber. The controller is programmed to maintain a flow rate of the boron precursor at less than X/min, wherein, under standard conditions, X is 6.2% or less of the volume of the reaction space.

### BRIEF DESCRIPTION OF THE DRAWINGS

FIG. 1 is a schematic, cross-sectional side view of a semiconductor processing reactor, in accordance with embodiments of the invention.

FIG. 2 is a graph showing the specific dielectric constants of deposited boron-containing nitride films as the ratio of boron precursor to other precursors is varied, in accordance with embodiments of the invention.

FIG. 3 is a graph showing changes in the leakage currents of deposited boron-containing nitride films as the ratio of boron precursor to other precursors is varied, in accordance with embodiments of the invention.

FIG. 4 is a graph showing changes in the deposition rate of deposited boron-containing nitride films as the total flow rate of silicon and boron precursors into the deposition chamber is varied and as the ratio of boron precursor to other precursors is varied, in accordance with embodiments of the invention.

FIG. 5 is a graph showing changes in the in-plane uniformities of deposited films as the ratio of the flow rate of N₂ to other process gases is varied and as the ratio of boron precursor to other precursors is varied, in accordance with embodiments of the invention.

FIG. 6 is a graph showing changes in the deposition rates of boron-containing nitride films as the ratio of the flow rate of N₂ to other process gases is varied and as the ratio of boron precursor to other precursors is varied, in accordance with embodiments of the invention.

FIG. 7 is a graph showing the FTIR spectra over time of boron-containing nitride films without using NH₃ as a process gas, in accordance with embodiments of the invention.

FIG. 8 is a graph showing the FTIR spectra over time of boron-containing nitride films using NH₃ as a process gas, in accordance with embodiments of the invention

### DETAILED DESCRIPTION OF SOME EMBODIMENTS

Films offering a relatively low dielectric constant and high diffusion prevention performance are useful not only as etch stop layers, but they can also be suitable for use in applications where SiN with a relatively high dielectric constant has heretofore been used. In these applications, the films can help to improve the operating speed of semiconductor devices and reduce cross-talk among wires.

To reduce the dielectric constant of a SiN film, the idea of introducing B to SiN films has been explored. For example, the formation of SiBN has been reported in the Japanese Journal of Applied Physics Vol. 26, No. 5, May 5, 1987, pp. 660-665. The films were formed with a lower flow rate of NH₃ relative to the flow rates of SiH₄ and B₂H₆, and without using N₂ as a process gas. However, the resulting SiBN films were not commercially acceptable.

Moreover, it has been difficult to form thin and uniform boron-containing nitrides. It will be appreciated that thin and low dielectric constant layers are desired in many applications, such as for etch stop layers. Since the majority of conventional thin-film forming technologies using plasma CVD target film thicknesses of several tens to several hundreds of nanometers, an attempt to grow a very thin film can be difficult. For example, forming a film of about 15 nm thick or less using these conventional technologies would require that the deposition occur for a very short film-forming time. This makes it difficult to control the thickness of deposited films by controlling the film forming time.

It will be appreciated that plasma CVD apparatuses typically use an impedance matching device to transmit high-frequency power to the electrodes in a process chamber. However, the time required to achieve an impedance-matched state can vary between matching devices. As a result, deposition results in different deposition chambers, which can have different impedance matching devices, can vary due to the time needed for impedance matching. For example, the time needed for impedance matching can be subject to a variation of about ±0.2 second due to individual differences between the matching devices. As a result, the actual film forming time can be subject to a variation of about ±0.2 second due to the differences between the matching devices. For forming thin films of about 15.7 nm or less, the film forming time may be 5.5 seconds or less for many deposition processes. Where the film forming time is less than 5.5 seconds, the actual film forming time can have a variation of over about 7% among the process chambers used for a deposition process. This is not acceptable for manufacturing semiconductor devices using mass-production facilities, since the use of multiple reactors in these facilities can give deposition results that vary depending upon the reactor used for the deposition. As a result, while faster deposition rates are typically desired for semiconductor fabrication processes, it has been found that it is beneficial to decrease the deposition rate of processes for forming films such as boron-containing nitrides, thereby allowing for improved control over the thickness of the deposited film. For example, it is beneficial to form a 15.7 nm thick film over a film forming time of 5.5 seconds or more. In such as case, the deposition rate is about 171 nm/min or less.

Preferred embodiments of the invention advantageously form films at a low deposition rate and also form films with high in-plane uniformity. Boron-containing films such as silicon boron nitrides (SiBN) or boron nitrides (BN) can be formed. In some embodiments, the films are formed on a substrate, e.g., a semiconductor wafer, by plasma-enhanced chemical vapor deposition (PECVD) using a silicon precursor and a boron precursor as precursor gases. Examples of silicon precursors include, without limitation, silanes such as monosilane (SiH₄). A example of a boron precursor is, without limitation, B₂H₆. The PECVD process chamber used for the deposition has a volume referred to herein as the reaction space. The reaction space is the open volume of the process chamber directly above a substrate loaded into the process chamber. The total combined feed rate of the silicon precursor and the boron precursor is X/minutes, wherein X is a volume of gas that is, under standard conditions, equal to or less than about 6.2% of the volume of the reaction space. It will be appreciated that, under the deposition conditions, X may be more or less than 6.2% of the volume of the reaction space. In some embodiments, N₂ is also flowed into the process chamber. The flow rate of N₂ is about 50 or more, or about 100 or more, times the total flow rate of the silicon precursor and the boron precursor. In addition, in some embodiments, the flow rate of the silicon precursor can be zero, for forming BN. In some embodiments, the deposition rate is about 200 nm/min or less, or about 171 nm/min or less. NH₃ can also be added to the precursor flow to improve the chemical stability of the deposited film.

advantageously, the low deposition rates allows for fine control of the thickness of deposited films over a range of several dozen nanometers by simply controlling the deposition time. In addition, the deposited films have an in-plane uniformity of about 3% or less and can be formed having a thickness of about 20 nm or less, or 15 nm or less. The high uniformity allows for the formation of high quality and highly reliable semiconductor devices.

In some embodiments, a substrate sits on a susceptor, which can be the lower electrode of a PECVD chamber, such that there is no open volume below the substrate. In this case, the volume of the reaction space refers to the open volume of the process chamber directly above the substrate. The reaction space volume is given by the following formula:

Substrate area×(Distance between upper and lower electrodes−Substrate thickness).

For example, for a 300-mm wafer having a thickness of 0.0775 cm disposed between upper and lower electrodes spaced 1 cm apart, the reaction space volume is equal to:

15.0 cm×15.0 cm×π×(1.0 cm−0.0775 cm)=652 cm³.

For a process chamber with such a reaction space volume, the flow rate of the silicon precursor and the boron precursor into the process chamber is about 40 sccm or less in some embodiments.

For example, in one embodiment, to deposit a film with a thickness of 15.7 nm in a deposition duration of 5.5 seconds or more, the deposition rate is about 171 nm/min or less. Advantageously, if the sum of flow rates of the silicon and boron precursors, e.g., SiH₄ and B₂H₆, is 40 sccm or less, the film forming speed is less than 171 nm/min regardless of the ratio of SiH₄ and B₂H₆. Advantageously, this allows good process latitude for forming silicon boron nitrides, e.g., by allowing the amount of boron incorporated into the film to be varied as desired while still maintaining a desirably low deposition rate.

The flow rate of N₂ relative to the sum of the flow rates of SiH₄ and B₂H₆ has been found to have minimal impact on the deposition rate, or film growth speed. However, in some embodiments, a relatively high N₂ flow rate is provided to improve the uniformity of the deposited film. Flowing N₂ at a flow rate of about 100 times or more of the combined flow rates of the silicon and the boron precursors (e.g., SiH₄ and B₂H₆) for SiBN films, or the flow rate of B₂H₆ for BN films advantageously forms a film with high uniformity, e.g., an in-plane uniformity of about 3% or less.

Reference will now be made to the drawings. It will be appreciated that subscripts are not provided in chemical formulas for ease of readability. Nevertheless, the skilled artisan will understand that numerals following chemical elements correspond to subscripted numerals in conventional chemical nomenclature.

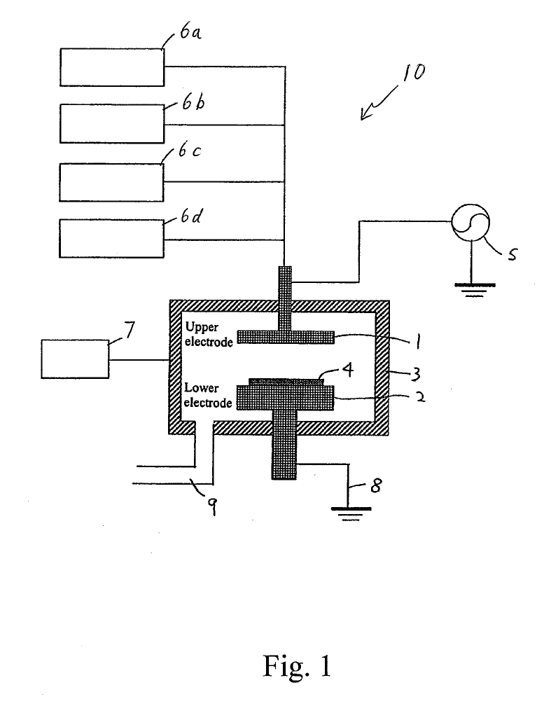

It will be appreciated that preferred embodiments of the invention can be applied to various chemical vapor deposition (CVD) apparatus known in the art. An advantageous and non-limiting example of one such apparatus is illustrated in FIG. 1.

With reference to FIG. 1, a CVD reactor 10 is illustrated. The reactor 10 can be a plasma CVD reactor which deposits material by a capacitively-coupled method. Films can be deposited on a substrate 4 by loading the substrate between a pair of electroconductive flat-plate electrodes (an upper electrode 1 and a lower electrode 2), which are arranged parallel to one another within a process chamber 3. The substrate 4 can be placed and supported on the lower electrode 2. It will be appreciated that the reaction space for the process chamber 3 is the open volume directly above the substrate 4 and extending from the substrate 4 to the upper electrode 1. During the plasma-enhanced deposition, an RF power 5 of, for example, approximately 13.56 MHz can be applied to one side of the electrodes and the other electrode 8 can be grounded, thereby exciting plasma between the electrodes. It will be appreciated that the frequency can be selected according to the type of source gas used. A temperature control mechanism is attached to the lower stage (lower electrode) 2 and, in some embodiments, the temperature is kept at a given constant temperature in the range of about 200° C. to about 600° C. In this state, process gases can be fed from sources 6a, 6b, 6c and/or 6d into the process chamber 3. Gas within the process chamber 3 is exhausted from an exhaust duct 9. A controller 7 controls the deposition conditions, including the flow of gases from the gas sources 6a, 6b, 6c and 6d to the process chamber 3, as discussed herein.

As can be seen in the Figures herein, preferred embodiments of the invention advantageously allow formation of boron-containing nitride films with a low dielectric constant and low leakage current. The boron-containing nitride films are formed with a relatively low deposition rate, thereby allowing for excellent thickness control. The films also have excellent thickness uniformity, preferably a thickness uniformity of about 3% or less. In addition, the films have excellent stability.

Table 1 provides some deposition conditions according to some embodiments of the invention. Advantageously, SiBN films formed under the film forming conditions shown in Table 1 have a dielectric constant lower than that of normal SiN, e.g., a dielectric constant lower than 7. It will be appreciated that, in other embodiments, the flow rate of the silicon precursor can be set at zero, so that the boron precursor constitutes the entire flow shown (100%) in the second and third columns from the left, thereby forming a BN film. Thus, in some embodiments, the boron precursor can be about 25%-100% of the flow rate for the third column from the left.

TABLE 1

| | SiH₄ + B₂H₆ | B₂H₆/(SiH₄ + B₂H₆) | N₂ | Pressure | HRF |
|---|---|---|---|---|---|
| Condition | [sccm] | [%] | [sccm] | [Pa] | [W] |
| Condition | 15 | 25~85 | 5000 | 400 | 800 |
| 1 | | | | | |

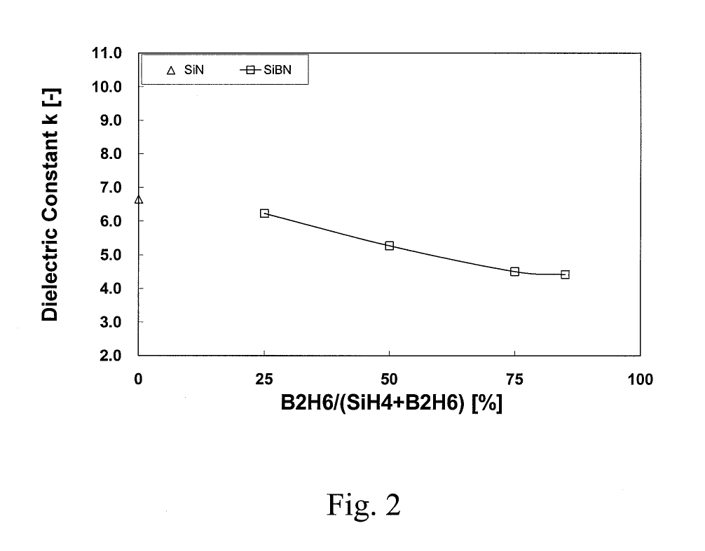

With reference to FIG. 2, the effect of changes in the ratio of the B₂H₆ flow rate to the combined flow rate of SiH₄ and B₂H₆ on the dielectric constant of a deposited SiBN film is shown. The SiBN films were deposited under the conditions shown on Table 1. The flow rate of B₂H₆ making up the total flow rate of SiH₄ and B₂H₆ was varied from about 25% to about 85%. While the specific dielectric constant of a normal SiN film that does not use B₂H₆ is about 6-7, use of B₂H₆ was found to decrease the specific dielectric constant of the deposited film. For example, it was possible to reduce the specific dielectric constant of the deposited SiBN film to about 4.5 using B₂H₆.

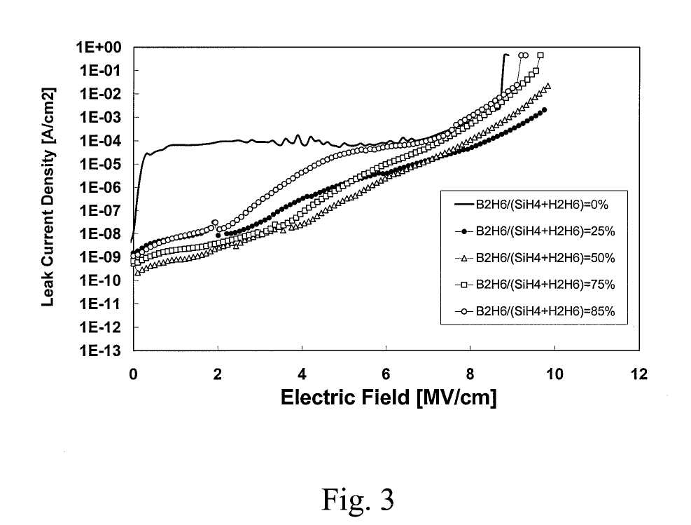

With reference to FIG. 3, a J-E plot diagram (I-V characteristics) is shown for SiBN films formed under the conditions of Table 1, with the ratio of the B₂H₆ flow rate to the combined flow rate of SiH₄ and B₂H₆ varied. It can be seem that the use of B₂H₆ in the deposition advantageously reduced the leak current. With continued reference to FIG. 3, the leak current of the SiN film formed without B₂H₆ is relatively high at about 3.7 E-05 A/cm² (@ 2 MV/cm), while the SiBN film formed with B₂H₆ has a reduced level of leak current at about 9.2 E-09 A/cm² (@ 2 MV/cm).

To form high quality SiBN or BN films with a target film thickness of about 200 nm or less or about 15 nm or less, the deposition rate is preferably low. While the deposition rate of the film varies slightly depending on the B₂H₆ ratio, it has been found that an advantageously low deposition rate, regardless of the ratio of B₂H₆, can be achieved by maintaining the combined feed rate of the silicon precursor and the boron precursor at X/minutes, where X is a volume of gas that is, under standard conditions, equal to or less than about 6.2% of the volume of the reaction space. Thus, the reaction space volume can be determined and the flow rate calculated based upon the reaction space volume. In some embodiments, a deposition rate of less than 171 nm/min, regardless of the B₂H₆ ratio, is achieved by keeping the sum of flow rates of B₂H₆ and SiH₄ at 40 sccm or less, where the reaction space volume is about 652 cm³. As a result, good controllability can be achieved in the formation of SiBN or BN film with a thickness of about 15 nm. Table 2 provides additional examples of film forming conditions according to some embodiments of the invention.

TABLE 2

| | SiH₄ + B₂H₆ | B₂H₆/(SiH₄ + B₂H₆) | N₂ | Pressure | HRF |
|---|---|---|---|---|---|
| Condition | [sccm] | [%] | [sccm] | [Pa] | [W] |
| Condition | 5~40 | 0~95 | 5000 | 400 | 800 |
| 2 | | | | | |

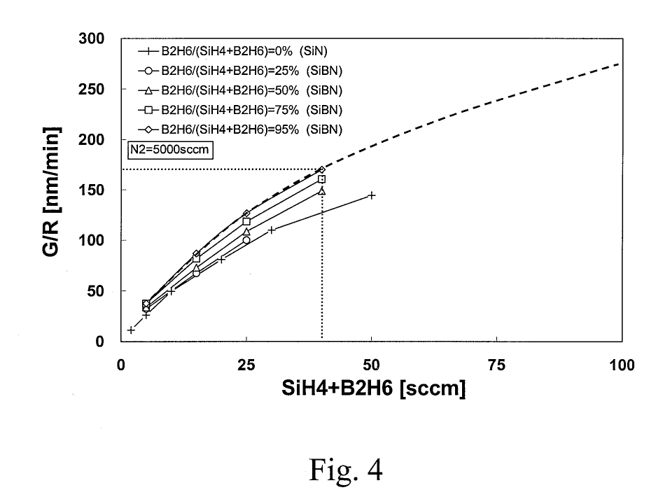

With reference to FIG. 4, SiBN films were deposited under various ratios of the flow rate of B₂H₆ to the combined B₂H₆ and SiH₄ flow rate. The deposition rate of the deposition was measured. At all ratios that were examined, a deposition rate of about 171 nm/min or less was achieved.

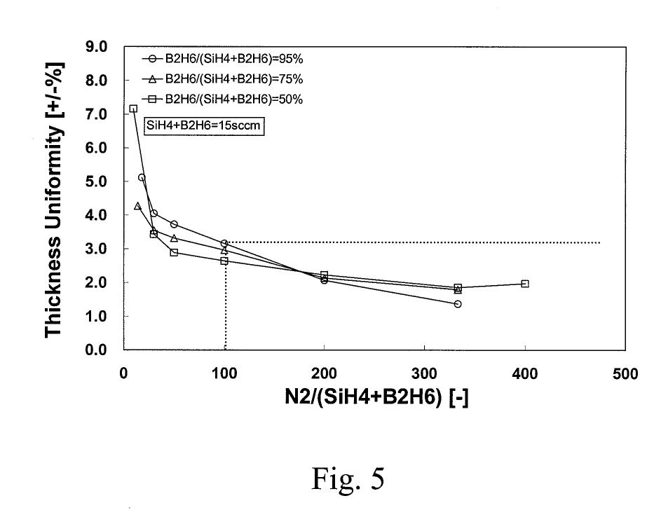

With reference to FIG. 5, the in-plane film thickness uniformities of the deposited films are shown as a function of the ratio of the N₂ flow rate relative to the total flow rate of B₂H₆ and SiH₄. By setting the N₂ flow rate to 100 times or more of the total flow rate of B₂H₆ and SiH₄, the in-plane uniformity was advantageously maintained at a level of about 3% or less.

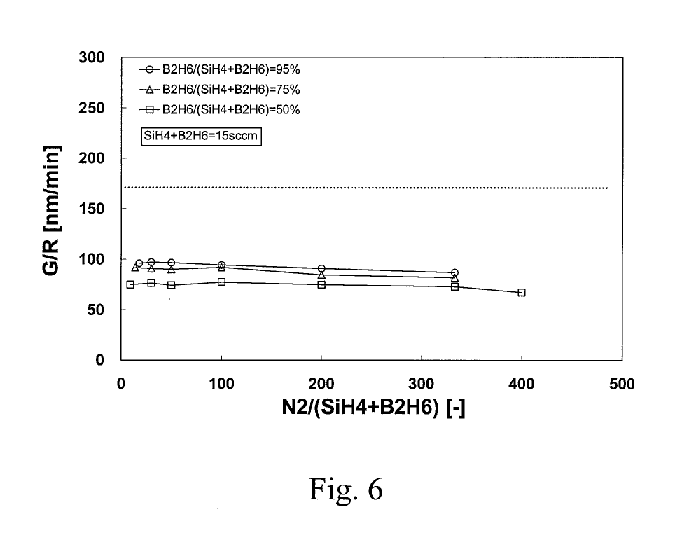

With reference to FIG. 6, the growth rates of the deposited films are shown as a function of the ratio of the N₂ flow rate relative to the total flow rate of B₂H₆ and SiH₄. Advantageously, changing this ratio was found to have minimal impact on the deposition rate. As a result, the in-plane film thickness uniformity can be controlled by maintaining the deposition rate at a sufficiently low level.

Thus, in some embodiments, a deposition rate of 171 nm/min or less and an in-plane film thickness uniformity of about 3% or less can be simultaneously achieved by setting the total flow rate of B₂H₆ and SiH₄ to 40 sccm or less while setting the N₂ flow rate to 100 or more times the total flow rate of B₂H₆ and SiH₄.

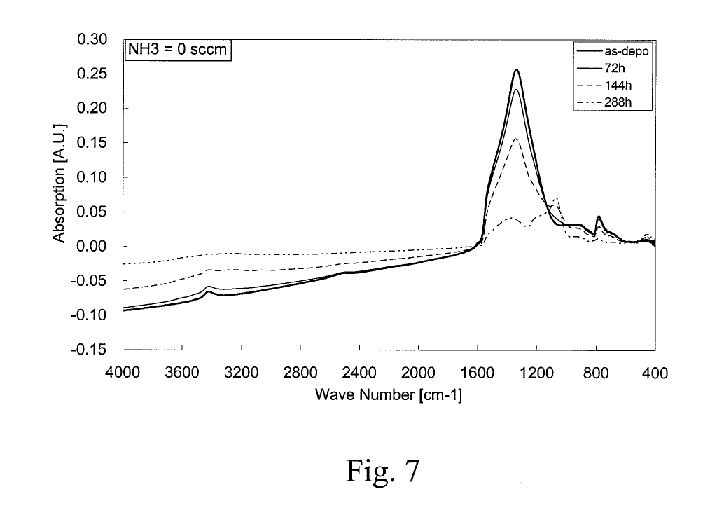

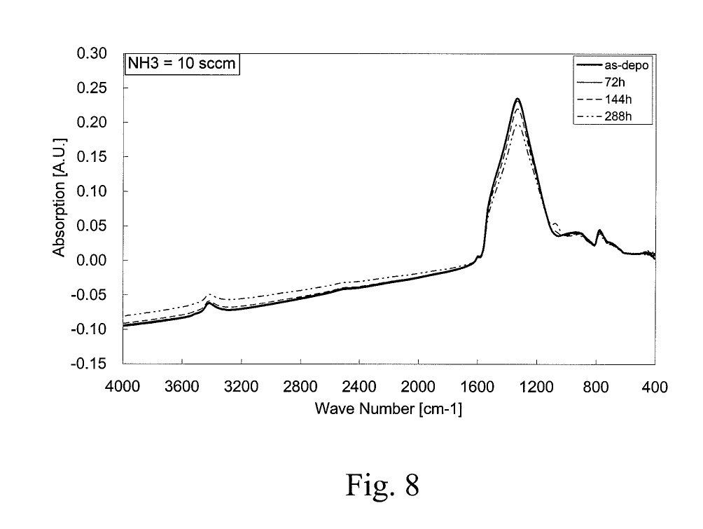

In some embodiments, changes in the deposited film over time can be suppressed by the additional of NH₃ during the film deposition. Non-limiting examples of deposition conditions are shown in Table 3 and FIGS. 7 and 8 show how the FTIR spectra of the deposited films change over time.

TABLE 3

| | SiH₄ + B₂H₆ | B₂H₆/(SiH₄ + B₂H₆) | N₂ | NH₃ | Pressure | HRF |
|---|---|---|---|---|---|---|
| Condition | [sccm] | [%] | [sccm] | [sccm] | [Pa] | [W] |
| Condition 3 | 15 | 75 | 5000 | 0 | 400 | 800 |
| Condition 4 | 15 | 75 | 5000 | 10 | 400 | 800 |

With reference to FIG. 7, FTIR spectra changes over time are observed for SiBN films formed without using NH₃. The peak near 1350 cm⁻¹ decreases over time. This suggests that B—N bonds in the film were severed over time due, e.g., to hydrolysis, etc., and the film quality changes as a result.

With reference to FIG. 8, FTIR spectra changes over time are observed for SiBN films formed using NH₃. Advantageously, the spectra changes little over time, indicating that the addition of the NH₃ stabilizes the deposited film. For example, changes in the peak corresponding to the B—N bonds were dramatically reduced relative to the films giving the spectra for FIG. 7.

It will also be appreciated by those skilled in the art that various omissions, additions and modifications may be made to the methods and structures described above without departing from the scope of the invention. All such modifications and changes are intended to fall within the scope of the invention, as defined by the appended claims.

We claim:

1. A method for forming a boron-containing nitride film, comprising:
providing a substrate in a process chamber having a reaction space, wherein the reaction space is an open volume directly above the substrate and extending between the substrate and an upper electrode of the process chamber; and
exposing the substrate to a boron precursor, a silicon precursor and N₂ by flowing the boron precursor, the silicon precursor and N₂ into the process chamber,
wherein a total volume, as measured under standard conditions, of the boron precursor and the silicon precursor flowed into the process chamber per minute is about 6.2% or less of the volume of the reaction space.

2. The method of claim 1, wherein the substrate is disposed between the upper electrode and a lower electrode, wherein a volume of the reaction space is given by the formula
Sₐᵣₑₐ×(Dₜₒₜₐₗ−S_{thickness}),
where Sₐᵣₑₐ is an area occupied by a major surface of the substrate;
Dₜₒₜₐₗ is a distance between the upper and the lower electrodes; and
S_{thickness} is a thickness of the substrate.

3. The method of claim 1, wherein the silicon precursor is SiH₄ and the boron precursor is B₂H₆.

4. The method of claim 1, wherein exposing the substrate to N₂ comprises flowing N₂ into the process chamber at a rate of about 50 or more times a total flow rate of SiH₄ and B₂H₆ into the process chamber.

5. The method of claim 4, wherein exposing the substrate to N₂ comprises flowing N₂ into the process chamber at a rate of about 100 or more times the total flow rate of SiH₄ and B₂H₆ into the process chamber

6. The method of claim 1, wherein flowing SiH₄ and B₂H₆ into the process chamber comprises flowing SiH₄ and B₂H₆ into the process chamber at a combined flow rate of about 40 sccm or less.

7. The method of claim 1, wherein B₂H₆ comprises about 25-85% of the flow of SiH₄ and B₂H₆ into the process chamber.

8. The method of claim 1, further comprising suppressing changes in B—N bonds over time by flowing NH₃ into the process chamber during exposing the substrate to SiH₄ and B₂H₆.

9. The method of claim 1, wherein providing the substrate comprises supporting the substrate on a lower electrode of the process chamber.

10. A method for semiconductor processing, comprising:
providing a substrate in a process chamber;
chemical vapor depositing a boron-containing nitride film on the substrate; and
terminating deposition of the boron-containing nitride film while a thickness of the deposited film is about 20 nm or less,
wherein an in-plane uniformity of the deposited boron-containing nitride film is about 3% or less.

11. The method of claim 10, wherein chemical vapor depositing the boron-containing nitride film deposits the boron-containing nitride film at a deposition rate of about 200 nm/min or less.

12. The method of claim 10, wherein the deposition rate is about 171 nm/min or less.

13. The method of claim 10, wherein chemical vapor depositing the boron-containing nitride film comprises flowing B₂H₆ and N₂ into the process chamber.

14. The method of claim 13, further comprising flowing a silicon precursor into the process chamber during depositing the boron-containing nitride film to form a SiBN film.

15. The method of claim 14, wherein the silicon precursor is a silane.

16. The method of claim 15, wherein the silane is monosilane.

17. The method of claim 14, wherein the thickness of the film is about 20 nm or less.

18. The method of claim 10, wherein chemical vapor depositing the boron-containing nitride film deposits the boron-containing film at a rate of about 180 nm or less per minute.

19. The method of claim 10, wherein a dielectric constant of the boron-containing nitride film is about 4.5 or less.

20. The method of claim 10, further comprising depositing an insulating layer on the boron-containing layer.

21. The method of claim 10, further comprising deposting an insulating layer on the boron-containing layer is an etch stop layer.

22. The method of claim 21, wherein etching comprises reactive ion etching.

23. A system for semiconductor processing, comprising:
a reactor comprising a process chamber for accommodating a substrate between upper and lower electrodes, the process chamber comprising a reaction space consisting of an open volume directly overlying the substrate and extending between the substrate and the upper electrode upon retention of the substrate in the process chamber;
a boron precursor source in gas communication with the process chamber;
a nitrogen precursor source in gas communication with the process chamber; and
a controller programmed to simultaneously flow the boron precursor and the nitrogen precursor into the process chamber, wherein the controller is programmed to maintain a flow rate of the boron precursor at less than X/min, wherein, under standard conditions, X is 6.2% or less of the volume of the reaction space.

24. The system of claim 23, further comprising a source of a silicon precursor in gas communication with the process chamber, wherein the controller is further programmed to flow the silicon precursor into the process chamber, the controller programmed to maintain a combined flow rate of the silicon and the boron precursors at less than X/min.
